(19) United States
(12) Patent Application Publication
(10) Pub. No.: US 2007/0148336 A1
(43) Pub. Date: Jun. 28, 2007

(54) PHOTOVOLTAIC CONTACT AND WIRING FORMATION

(76) Inventors: Robert Bachrach, Burlingame, CA (US); Quanyuan Shang, Saratoga, CA (US); Yan Ye, Saratoga, CA (US)

Correspondence Address: PATTERSON & SHERIDAN, LLP, 3040 POST OAK BOULEVARD, SUITE 1500, HOUSTON, TX, 77056, US

(21) Appl. No.: 11/556,776

(22) Filed: Nov. 6, 2006

Related U.S. Application Data
(60) Provisional application No. 60/734,410, filed on Nov. 7, 2005.

(51) Int. Cl. B05D 5/12; H05K 3/00; C23C 16/00

(52) U.S. Cl. 427/97.1; 427/97.3; 427/97.4; 427/98.4; 427/98.8; 427/99.2; 427/255.7

(57) ABSTRACT

A method and apparatus for fabricating a solar cell and forming metal contact is disclosed. Solar cell contact and wiring is formed by depositing a thin film stack of a first metal material and a second metal material as an initiation layer or seed layer for depositing a bulk metal layer in conjunction with additional sheet processing, photolithography, etching, cleaning, and annealing processes. In one embodiment, the thin film stack for forming metal silicide with reduced contact resistance over the sheet is deposited by sputtering or physical vapor deposition. In another embodiment, the bulk metal layer for forming metal lines and wiring is deposited by sputtering or physical vapor deposition. In an alternative embodiment, electroplating or electroless deposition is used to deposit the bulk metal layer.

### CROSS-REFERENCE TO RELATED APPLICATIONS

This application claims benefit of U.S. provisional patent application Ser. No. 60/734,410, filed Nov. 7, 2005, which is herein incorporated by reference.

### BACKGROUND OF THE INVENTION

1. Field of the Invention

Embodiments of the present invention generally relate to photovoltaic/solar cell and solar panel manufacturing.

2. Description of the Related Art

Photovoltaics (PV) systems can generate power for many uses, such as remote terrestrial applications, battery charging for navigational aids, telecommunication equipments, and consumer electronic devices, such as calculators, watches, radios, etc. One example of PV systems includes a stand-alone system which in general powers for direct use or with local storage. Another type of PV system is connected to conventional utility grid with the appropriate power conversion equipment to produce alternating current (AC) compatible with any conventional utility grid.

PV or solar cells are material junction devices which convert sunlight into direct current (DC) electrical power. When exposed to sunlight (consisting of energy from photons), the electric field of solar cell p-n junctions separates pairs of free electrons and holes, thus generating a photo-voltage. A circuit from n-side to p-side allows the flow of electrons when the solar cell is connected to an electrical load, while the area and other parameters of the PV cell junction device determine the available current. Electrical power is the product of the voltage times the current generated as the electrons and holes recombine.

Currently, solar cells and PV panels are manufactured by starting with many small silicon sheets or wafers as material units and processed into individual photovoltaic cells before they are assembled into PV module and solar panel. These silicon sheets are generally saw-cut p-type boron doped silicon sheets less than about 0.3 mm thick, precut to the sizes and dimensions that will be used, e.g., 100 mm×100 mm, or 156 mm×156 mm. The cutting (sawing) or ribbon formation operation on the silicon sheets leaves damage to the surfaces of the precut silicon sheets, and etching processes, e.g., using alkaline or acid etching solutions, are performed on both surfaces of the silicon sheets to etch off about ten to twenty microns in thickness from each surface and provide surface textures thereon.

Junctions are then formed by diffusing an n-type dopant onto the precut p-type silicon sheets, generally performed by phosphorus diffusion as phosphorus is universally used as the n-type dopant for silicon in solar cells. One example to perform phosphorus diffusion includes coating phosphosilicate glass compounds onto the surface of the silicon sheets and carrying out diffusion/annealing inside a furnace. Another example of diffusing a phosphorus dopant to silicon includes bubbling nitrogen gas through liquid phosphorus oxychloride (POCl₃) sources which are injected into an enclosed quartz furnace loaded with batch-type quartz boats containing the silicon sheets. Typically, a high temperature is needed to form and create a p-n junction depth of about 0.1 microns up to about 0.5 microns. One or both surfaces of a PV cell can also be coated with suitable dielectrics after the p-n junction is formed. Dielectric layers are used to minimize surface charge carrier recombination and some dielectric materials, such as silicon dioxide, titanium dioxide, or silicon nitride, can be provided as antireflective coating to reduce reflection losses of photons.

The front or sun facing side of the PV cell is then covered with area minimized metallic contact grid for transporting current and minimizing current losses due to resistance through silicon-containing layers. Some blockage of sunlight or photons by the contact grid is unavoidable but can be minimized. The bottom of the PV cell is generally covered with a back metal which provides contact for good conduction as well as high reflectivity. Metal grids with patterns of conductive metal lines are used to collect current. Generally, screening printing thick-film technology is used in the PV cell industry to layer a conductive paste of metal materials, e.g., silver, etc., into a desired pattern and deposit a metal material layer to the surface of the silicon sheets or substrates for forming metal contact fingers or wiring channels on the front and/or back side of the solar cell. Other thin film technologies may be used for contact formation or electrode processing. The deposited metal layer, formed into contacts, is often dried and then fired or sintered at high temperature to form into good conductors in direct contact with underlying silicon materials, and a single PV cell is made. Generally, both silver and aluminum are contained in the screen printing paste for forming back side contacts with good contact conductor to silicon material and easy soldering.

To create a solar panel appropriately sized to deliver the needed amount of power output and wired to achieve the desired operating voltage and current, a number of individual PV cells are tiled together and arrayed. For example, several PV cells may be interconnected in series or parallel electrical circuits into a PV module. A number of PV modules can also be assembled into pre-wired panels or arrays. Interconnection wiring of each PV cell into strings or modules is performed by soldering and wiring metal tabs and auxiliary tabs together. Generally, metal tabs are soldered to bus bars on the surface of a PV cell to wire metal contacts or metal fingers on each PV cell, provide interconnect links between PV cells, and allow thermal expansion. Currently, various wiring/interconnect schemes can be used for contact patterning and current collection, such as schemes using both front and back side wiring, schemes using front side current collection but all the contacts are brought to the back side, and other wiring schemes.

PV modules or panels are then bonded to or sealed in protective laminates or encapsulating barriers, such as ethylene vinyl acetate (EVA) sheets, and covered with a front glass pane and a back pane, which are glass cover plates protecting the PV cells and providing structural re-enforcement. Protection of the active PV devices during module construction directly affects the performance and lifetime of the final PV systems. Regardless of size, a single PV cell generally produces about 0.5-0.6 volt DC current. A common configuration uses about 36 connected PV cells for a maximum of about 15 volts, compatible with major appliances and appropriate for 12 volts battery charging.

Optimized solar cells usually mean maximum power generated by solar cell junction devices at minimum cost. Although screening printing of silver paste has been used for creating contact and wiring on solar cell silicon sheets, the resulting silver or aluminum thick films formed by coarser metallization techniques may not provide all the requirements of high quality metal lines, such as low contact resistance to silicon, low bulk resistivity, low line width and high aspect ratio, good adhesion, compatible with encapsulating materials, etc. For example, these thick film processes may give rise to decreased solar cell efficiency when larger sheet sizes are used, due to increased resistance of the metal lines. In addition, silver is a relative expensive material and a great amount of contact materials are lost. Further, screening printing process may not be compatible with some metal materials, such as copper, having low resistivity.

Therefore, there is a need for processes that are technically better and less expensive to form and manufacture solar cell contact and wiring.

### SUMMARY OF THE INVENTION

Aspects of the invention provide methods and apparatuses of forming solar cell contact and wiring. Solar cell contact and wiring is formed by depositing a thin film stack of a first and a second metal material as an initiation layer or seed layer for depositing a bulk metal layer in conjunction with additional silicon sheet processing, photolithography, etching, cleaning, and annealing processes.

In one embodiment, the thin film stack for forming metal silicide with reduced contact resistance over the silicon sheet is deposited by sputtering or physical vapor deposition. In another embodiment, the bulk metal layer for forming metal lines and wiring is deposited by sputtering or physical vapor deposition. In an alternative embodiment, electroplating or electroless deposition is used to deposit the bulk metal layer.

In one aspect, a method for forming metal contact and wiring on a sheet includes depositing an antireflective coating layer on the surface of the sheet, forming a pattern of a photoresist material for contact metallization on the surface of the sheet, curing the photoresist material, etching the antireflective coating layer through the pattern of the photoresist material, and cleaning the surface of the sheet. The method further includes depositing a film stack having the first metal material and a second metal material over the surface of the sheet inside a physical vapor deposition chamber, stripping the photoresist material off the surface of the sheet, annealing the sheet for forming good contact between the film stack and the sheet, and depositing a bulk metal material over the surface of the sheet. The antireflective coating layer may include silicon nitride formed inside a chamber, such as a plasma enhanced chemical vapor deposition chamber (PECVD) and a physical vapor deposition chamber (PVD). The pattern of the photoresist material may be formed by inkjet printing. In addition, the first metal material may include nickel, titanium, molybdenum, and their alloys, among others.

In another aspect, a method for forming metal contact and wiring on a sheet includes depositing an antireflective coating layer on the surface of the sheet, forming a pattern of a photoresist material for contact metallization on the surface of the sheet, using the photoresist material, etching the antireflective coating layer through the pattern of the photoresist material, cleaning the surface of the sheet; and depositing a film stack having the first metal material and a second metal material over the surface of the sheet inside a physical vapor deposition chamber. The method further includes depositing a bulk metal material over the surface of the sheet inside an electroplating system or an electroless deposition system.

In still another aspect, various physical vapor deposition chambers, electroplating systems, and/or electroless deposition systems are provided for fabricating a solar cell on a sheet.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a process flow diagram illustrating an exemplary method incorporating one embodiment of the invention.

FIG. 1B is a process flow diagram illustrating an exemplary method incorporating another embodiment of the invention.

FIG. 1C is a process flow diagram illustrating an exemplary method incorporating additional embodiment of the invention.

FIGS. 2A-2E are schematic cross-sectional views of an exemplary sheet having contact and wiring formed in accordance with various embodiments of the invention.

FIGS. 3A-3F are schematic cross-sectional views of another exemplary sheet having contact and wiring formed in accordance with various embodiments of the invention.

FIGS. 4A-4B are schematic cross-sectional views of still another exemplary sheet having contact and wiring formed in accordance with various embodiments of the invention.

FIG. 5 is a schematic cross-sectional view of an exemplary process chamber in accordance with one embodiment of the invention.

FIG. 6 is a schematic cross-sectional view of another exemplary process chamber in accordance with another embodiment of the invention.

### DETAILED DESCRIPTION

The present invention provides a novel approach for fabricating a solar cell and forming contact metallization and wiring on a solar cell sheet. In one embodiment, sputtering is used to deposit a thin film of metal materials on the solar cell sheet for forming metal contacts. In an alternative embodiment, electroplating or electroless deposition is used to selectively forming metal contact at high aspect ratio. In another embodiment, contact metallization and wiring formation are performed on the front side and/or the back side of a sheet using methods and apparatuses of the invention.

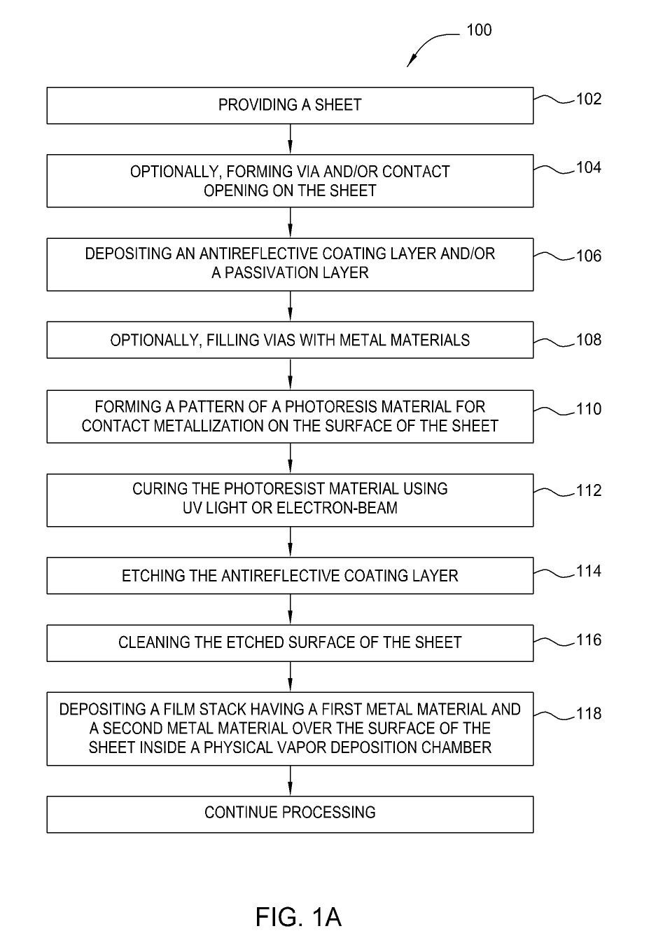

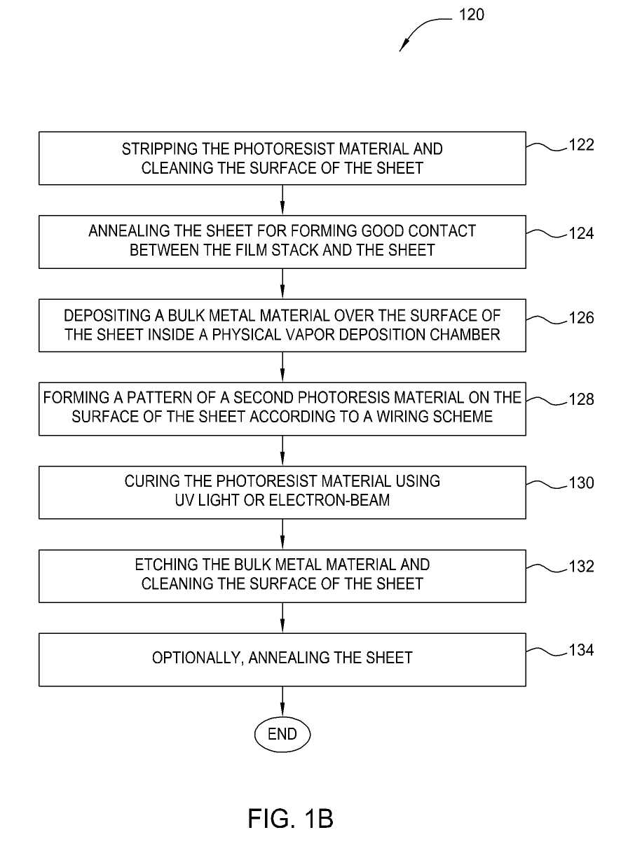

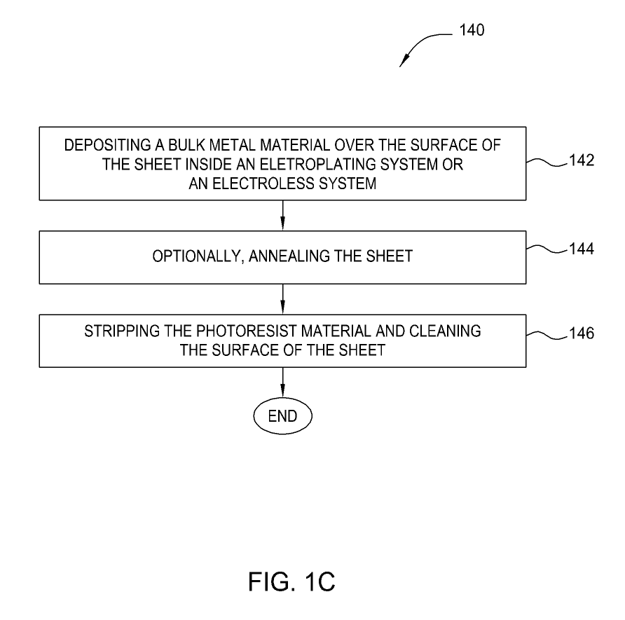

FIG. 1A depicts a process flow diagram illustrating one method 100 according to one exemplary embodiment of the invention. At step 102, a substrate or a silicon sheet is provided for forming contact and wiring thereon according to a predetermined wiring scheme. The substrate or sheet of the invention can be any of the starting materials suitable for PV cell and solar module fabrication, e.g., monocrystalline silicon, polycrystalline silicon, amorphous silicon, silicon ribbon sheet, cadmium telluride, gallium arsenide, polymer, plastic, organic material, among others. The shape of the sheet can vary, e.g., single crystal silicon wafer shape, quasi-square form, etc., and the sheet is not limiting and can be any sheet or substrate comprised of silicon, polymer, composite, metal, plastic, wafer or glass materials. The silicon sheet may optionally include one or more layers or features thereon, including p-n junctions, passivation films, dielectric materials, electrodes, vias, openings, plugs, among others. For example, each sheet may contain a single p-n junction, a dual junction, a triple junction, tunnel junction, p-i-n junction, or any other types of p-n junctions created by suitable semiconductor materials for solar cell manufacturing. It should be noted that the terms silicon sheet, substrate, or sheet, as used herein is intended to broadly describe a substrate, wafer, silicon-containing sheet, glass substrate, or ribbon that can be used to form a solar cell or other similar semiconductor type devices thereon.

In one embodiment, a sheet suitable for solar cell fabrication is used. A sheet size of about 50 mm×50 mm or larger can be used. Typical sheet size for solar cell fabrication may be about 100 mm×100 mm or larger, such as about 156 mm×156 mm or larger in size; however, smaller or lager sizes/dimensions can also be used to advantage, e.g., a size of about 400 mm×500 mm can also be used. The thickness of a solar cell sheet may, for example, be a few hundreds microns, such as between about 100 microns to about 350 microns.

At step 104, patterning and forming a feature, such as via and/or opening, may be optionally performed on the surface of the substrate or sheet. In one embodiment, the sheet of the invention may include vias formed for front side and/or back side contact and wiring before contact metallization. For example, drilling vias for back side contact can be performed by laser drilling or suitable etching techniques. Laser drilling can be performed according to a pattern for via formation without the use of a mask while a mask is generally required during etching. One example of a chemical mechanical jet etch process is described in U.S. Pat. No. 6,699,356, entitled “Method and Apparatus for Chemical Mechanical Jet Etching of Semiconductor Structures,” issued to Bachrach et al. and assigned to Applied Materials, Inc., which is hereby incorporated by reference to the extent not inconsistent with the disclosure herein.

At step 106, an antireflective coating layer and/or a passivation layer is deposited on the surface of the sheet or substrate. For example, a layer of silicon nitride or silicon oxide material may be used as the antireflective coating layer and/or the passivation layer and can be deposited inside a chemical vapor deposition chamber, such as a plasma enhanced chemical vapor deposition chamber using a mixture of silicon-containing precursor and nitrogen-containing precursor. The chemical vapor deposition chamber can be a stand-alone chamber or as part of a multi-chamber substrate processing system in conjunction with methods and apparatuses of the invention.

In one example, a silicon nitride layer having a thickness between about 20 nm and 500 nm, such as a thickness of about 50 nm to about 250 nm, e.g., about 70 nm to about 200 nm, may be deposited to the front and back side of the sheet as well as to the via walls from a mixture of silane gas, ammonium gas, hydrogen gas, and/or nitrogen gas and is provided as a barrier layer, encapsulating layer, and/or antireflective coating. Other suitable materials for the antireflective coating layer and/or the passivation layer include various dielectric materials, such as titanium oxide, amorphous carbon material, etc., suitable for use in PV cells exposed to the solar flux. The absorption coefficient of the antireflective coating materials should be minimized but can vary. Additional layers of anti-reflection coating can be deposit for better index matching, such as a second front side dielectric antireflective coating layer.

Optionally, vias on the surface of the sheet are filled with metal materials at step 108. Vias and features can be filled using various suitable techniques, such as inkjet printing, among others.

Next, at step 110, a pattern of a photoresist material for contact metallization is formed on the surface of a sheet in accordance with a predetermined contact pattern. In one embodiment, suitable photoresist materials are patterned on the surface of the sheet to a thickness of about 100 nm to about 600 nm, such as about 400 nm. Suitable photolithography patterning techniques can be used, for example, an inject printing technique can be used to form a pattern of the photoresist material. In addition, an optional dielectric layer or silicon oxide layer can be deposited prior to patterning the photoresist material to be served as an etching mask.

At step 112, the photoresist material is cured using suitable photolithography techniques, for example, by exposure to UV light or electron-beam, and the antireflective coating layer is etched at step 114. Suitable dry etching or wet etching techniques can be used depending on the materials of the antireflective coating/passivation layer. For example, silicon nitride can be etched according to the pattern of the photoresist material using a wet etch chemistry of phosphoric acid at high temperatures, e.g., at around 175° C.

Next, at step 116, the surface of the sheet is cleaned, such as using suitable post-etch cleaning chemistries and/or rinsing with water. For example, the surface of the sheet can be cleaned by wet chemical etching in diluted hydrofluoric acid (HF) solutions. Other techniques, such as various dry cleaning techniques, can also be used.

At step 118, a film stack is deposited over the cleaned sheet surface in accordance with one or more embodiments of the invention. In one embodiment, the film stack may include a first metal material which formed into a metal silicide material with the sheet and reduce contact resistance of the devices fabricated on the sheet. Examples of the first metal material include, but not limited to, titanium, molybdenum, their alloys, and the combinations thereof, etc. In another embodiment, the film stack may include a second metal material which provides low resistivity for the devices fabricated on the sheets. Examples of the second metal material include, but not limited to, copper, aluminum, silver, their alloys, and combinations thereof, etc. Forming aluminum or copper contact and wiring has cost and performance advantages and can be readily incorporated into the processes described herein.

The invention provides that contact metallization is formed by a thin film technology, as compared to a thick film screen printing method. In accordance with one embodiment of the invention, sputtering or physical vapor deposition technique is employed to form the film stack providing good contact with a silicon-containing substrate or sheet. One example of a physical vapor deposition process and deposition apparatus is described in U.S. patent application Ser. No. 11/213,662, entitled “Integrated PVD System Using Designated PVD Chambers,” filed on Aug. 26, 2005 by Hosokawa et al. and assigned to Applied Materials, Inc.; another example, is described in U.S. patent application Ser. No. 11/185,535, entitled “Hybrid PVD-CVD Systems,” filed on Jul. 19, 2005 by Takehara et al. and assigned to Applied Materials, Inc.; all of which are hereby incorporated by reference to the extent not inconsistent with the disclosure herein.

The thicknesses of the first and the second metal materials may vary. In one embodiment, the thickness of the first metal material is smaller than the thickness of the second metal material. For example, the first metal material can be deposited to a thickness of about 5 nm to about 100 nm, such as between about 40 nm to about 80 nm or at about 30 nm. In addition, the second metal material can be deposited to a thickness of about 50 nm to about 300 nm, such as between about 100 nm to about 250 nm, e.g., at about 170 nm. In another embodiment, the film stack containing the first and the second metal material is deposited as an initial layer or seed layer of a bulk metal material for additional contact metallization and wiring formation.

Accordingly, contact metallization of a solar cell using the method 100 of the invention can be continued to form a wiring pattern using the method 120 or, alternatively, the method 140 in order to complete an overall solar cell fabrication scheme. FIG. 1B depicts a process flow diagram illustrating a method 120 for additional sheet processing after the sheet is processed by the method 100 in accordance with one or more embodiments of the invention.

At step 122, the sheet processed by the method 100 is used and the photoresist material is stripped off the sheet having a thin film stack deposited thereon. After photoresist stripping, the surface of the sheet may be optionally cleaned, such as by rinsing with water. Stripping is performed using suitable solvents, e.g., acetone, among others. The resulting sheet surface may include a pattern of the film stack of the invention formed on the layer of the antireflective coating/passivation material.

At step 124, the sheet is annealed at high temperature, such as about 200° C. or higher, such that metal silicide is formed at the bottom of the film stack of the invention for forming good contact with reduced contact resistance. Exemplary metal silicides include titanium silicide, molybdenum silicide, among others.

Next, at step 126, a bulk metal material is deposited over the surface of the sheet to continue the height of the metal contact. In one embodiment, the bulk metal material is the same metal material as the second metal material. In another embodiment, the bulk metal material is deposited by sputtering inside a physical vapor deposition chamber. Other film deposition techniques can also be used. The bulk metal material may include copper, aluminum, silver, their alloys, and combinations thereof, among others. Silver is commonly used as a solar cell wiring material, but aluminum or copper wiring has cost and performance advantages. The thickness of the bulk metal material for wiring formation is not limited, depending on the requirements of different wiring schemes, and can be about 500 nm or larger, such as about 5,000 nm or larger, or between about 5,000 nm and 10,000 nm.

At step 128, to continue wiring formation, a pattern of a second photoresist material is formed on the surface of the sheet in accordance with a predetermined wiring scheme. In one embodiment, suitable photoresist materials are patterned on the surface of the sheet to a thickness of about 100 nm to about 600 nm, such as about 400 nm, using an inject printing technique or other suitable techniques. Additional dielectric layers or silicon oxide layers can be deposited prior to patterning the photoresist material to be served as an etching mask.

At step 130, the photoresist material formed into a wiring pattern is cured. For example, the photoresist material can be cured by exposure to UV light, electron-beam, or using suitable photolithography techniques.

At step 132, the bulk metal material is etched using suitable metal etching chemistries in combination with dry or wet etching techniques. As a result, a pattern of the bulk metal material is formed into desired contact lines, contact fingers, and/or wiring patterns on the surface of the sheet.

Next, the surface of the sheet is cleaned after metal etching, using suitable post-etch cleaning chemistries and/or rinsing with water. For example, the surface of the sheet can be cleaned by wet chemical etching in diluted hydrofluoric acid (HF) solutions. Other techniques, such as various dry cleaning techniques, can also be used.

At step, 134, optionally, the sheet is annealed. For example, when copper is deposited as the bulk metal material, the grain size of the as-deposited copper is considerable large and annealing at a temperature of about 150° C. or larger, such as at about 200° C., is required to reduce copper grain size in order to lower the resistance of the metal wiring.

FIG. 1C depicts another process flow diagram illustrating a method 140 for additional sheet processing after the sheet is processed by the method 100 in accordance with one or more embodiments of the invention. At step 142, the sheet processed by the method 100 having the first and second metal materials deposited thereon is used as a seed layer material and a bulk metal material, which can be the same or different metal material as the second metal material of the film stack of the invention as described in the method 100, is deposited over the surface of the sheet to continue the height of the metal contact. Examples of the bulk metal material may include copper, aluminum, silver, among others, deposited to a thickness of about 100 nm or larger, such as about 1,000 nm or larger.

In one embodiment, the bulk metal material is deposited by an electroplating sheet processing system. Other film deposition techniques can also be used. One example of an electroplating process and sheet plating system is described in U.S. Pat. No. 6,258,220, entitled “Electro-Chemical Deposition System,” by Dordi et al. and assigned to Applied Materials, Inc.; another example, is described in U.S. patnet application Ser. No. 10/266,477, entitled “Tilted Electrochemical Plating Cell with Constant Wafer Immersion Angle,” filed on Oct. 7, 2002, by Lubomirsky et al. and assigned to Applied Materials, Inc.; all of which are hereby incorporated by reference to the extent not inconsistent with the disclosure herein.

In another embodiment, the bulk metal material is deposited by an electroless deposition system. One example of an electroplating process and sheet plating system is described in U.S. patent application Ser. No. 10/036,321, entitled “Electroless Plating System,” filed on Dec. 26, 2001 by Stevens et al. and assigned to Applied Materials, Inc.; another example, is described in U.S. Pat. No. 6,258,223, entitled “In-Situ Electroless Copper Seed Layer Enhancement in an Electroplating System,” by Cheung et al. and assigned to Applied Materials, Inc.; all of which are hereby incorporated by reference to the extent not inconsistent with the disclosure herein.

At step, 144, optionally, the sheet is annealed to form good contact between the metal materials and junctions within the sheet and cure the materials deposited on the surface of the sheet. For example, when copper is plated on the sheet surface, it is usually needed to further anneal the as-plated at a temperature of about 150° C. or larger, such as at about 200° C., to reduce copper grain size and lower the resistance of the metal wiring during solar cell fabrication.

At step 146, the photoresist material which has been patterned and cured by the method 100 of the invention can be stripped off the surface of the sheet. In addition, the surface of the sheet may be optionally cleaned and dried after photoresist stripping, such as by rinsing with water. Stripping is performed using suitable solvents, e.g., acetone, among others. The resulting sheet surface may include a pattern of the film stack and bulk metal material of the invention formed on the layer of the antireflective coating/passivation material. As a result, a pattern of the bulk metal material is revealed after stripping off the photoresist material and desired contact lines, contact fingers, and/or wiring patterns are formed on the surface of the sheet.

In accordance with one or more embodiments of the invention, contact metallization and wiring pattern formation are performed in two metallization phases, a first phase of forming a metal film stack with low contact resistance and a second phase of forming a bulk metal wiring pattern with low wiring resistance. The metal film stack can be preferably formed by thin film deposition techniques, such as by sputtering or physical vapor deposition. Deposition of the bulk metal material for forming a wiring pattern may be performed by various deposition techniques, such as sputtering, physical vapor deposition, electroplating, electroless deposition, among others. Further embodiments of the invention include performing the steps of the methods 100, 120, 140, not necessarily in the same order as illustrated in FIGS. 1A-1C. For example, the steps of the method 140 can be in a different order and the phtoresist material can be stripped off the surface of the sheet to form a pattern of the first and the second metal materials before the bulk metal material can be plated onto the surface of the sheet, as described at step 142, using the film stack containing the first and the second metal materials as a seed layer.

In one embodiment, the steps of the method 100, 120, and 140 may need to be repeated such that one or both surfaces of the sheet are processed by the methods of the invention to form contact and wiring on the sheet. The deposition and annealing processes as described in the method 100 of the invention result in more effective junction formation and eliminate gaseous diffusion steps, difficult gas sources and liquid sources, or any complex clean up steps which are required before and after sheet processing, as compared to prior art phosphorus diffusion processes.

Further, Contact metallization and wiring of a solar cell using the method 100 of the invention can be continued using the method 120 or, alternatively, the method 140 in order to complete an overall solar cell fabrication scheme. In addition, additional layers can be deposited on a substrate or a silicon sheet before and/or after processing by the methods 100,120, and 140. For example, one or more passivation layer or anti-reflective coating layer can be deposited on the front and/or back side of the sheet. In addition, a plurality of features can be patterned on the sheet using any of suitable patterning techniques, including, but not limited to, dry etch, wet etch, laser drilling, chemical mechanical jet etch, and combinations thereof. Suitable features include vias, contacts, contact windows, trenches, among others. Various antireflective coating materials can be used, including various dielectric materials, such as silicon nitride, titanium oxide, amorphous carbon material, etc., suitable for use in PV cells exposed to the solar flux. The absorption coefficient of the antireflective coating materials should be minimized but can vary. In one example, a silicon nitride layer at a thickness of about 70 nm to about 80 nm can be deposited to the front and back side of the sheet as well as to the via walls and provide as a barrier layer, encapsulating layer, and/or antireflective coating. Optionally, additional layers of anti-reflection coating can be deposit for better index matching, such as a second front side dielectric antireflective coating layer.

Using methods and apparatuses of the invention, contacts, such as electrodes, contact windows, wiring channels, among others, can be formed on the front and/or back side of the sheet. Further, current collection wirings can be formed on the front or back side of the sheet in accordance with on eor more embodiments of the invention. Additional metallization and film deposition required for fabricating different types of solar cell can be performed, depending on different applications used for laboratorial or industrial uses. Various types of PV cells may be desired to manufacture into a solar panel, including, Passivated Emitter Rear Locally diffused (PERL) cell, thin film silicon cell, Passivated Emitter Rear Totally diffused (PERT) cell, Zone-Melting Recrystallization (ZMR) cell, Surface Texture and enhanced Absorption with a back Reflector (STAR) cell, among others. For example, in some cases, metallization processing on the back side of the sheet in addition to front side sheet processing may be optionally performed to deposit high reflectivity materials using methods of the invention before the sheet is ready to be manufactured into a solar module or panel.

Next, one or more sheets that have been processed by one or more steps of the invention as described above may be arranged on a wiring backplane for fabricating into a solar module/panel, such as by tiling up a number of the sheets of the invention on the wiring plane. The wiring plane can be any of the insulating wiring back planes suitable for PV module manufacturing, such as a metal foil or a thick metal film on a plastic film with suitable insulating and barrier properties. In addition, the wiring backplane may include appropriate conductor patterns thereon for conducting current between PV cells with minimal resistivity loss. The backplane conductor patterns are designed to match with the design of the wiring scheme for the sheet of the invention and individual PV cell. Forming or patterning a layer of a metal conductor on the wiring backplane creates the needed wiring. The wiring pattern reflects the needed connections for each of the final solar cell. The wiring conductor patterns can be any of the suitable series-parallel organization (interconnection), depending on the design and intended use of the final solar panel to achieve the specified operative voltage and current. Bonding of the one or more sheets to the wiring plane can be perform by suitable techniques, including, not limited to, soldering with or without lead, epoxy, thermal annealing, ultrasonic annealing, among others. Then, the solar panel assembly can be bonded to additional protective films. One exemplary protective film is DuPont™ Tedlar® PVF (poly-vinyl fluoride). Protective films can be bonded to the back side of the wiring backplane to protect the conductor patterns and electrical output leads thereon from environmental corrosion or other damages while lightening the overall structure.

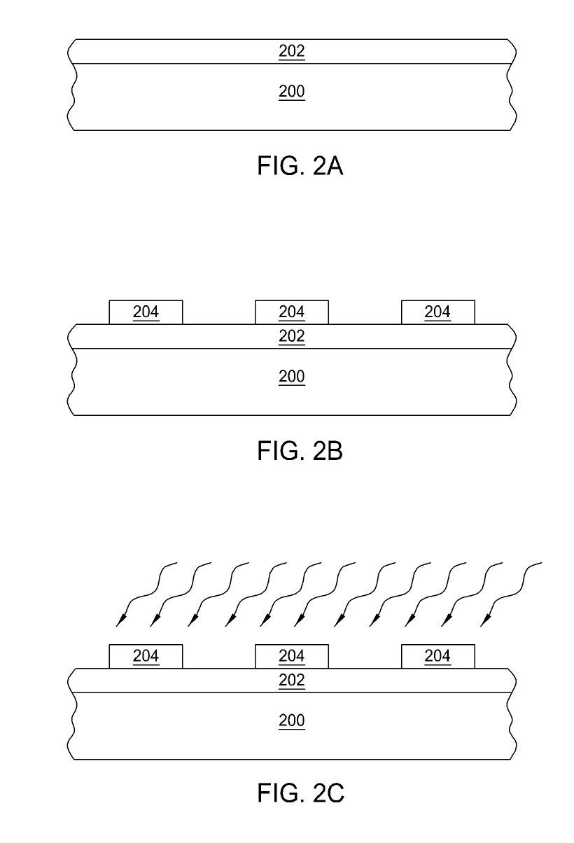

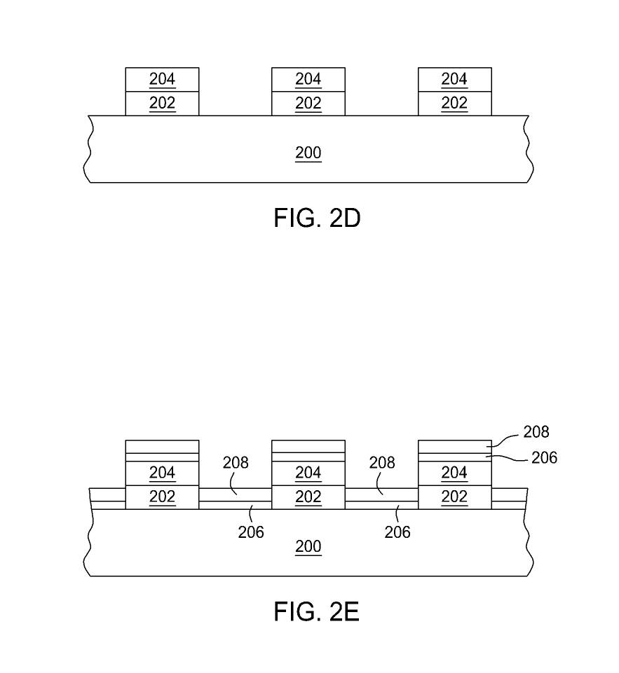

Generally, one or more sheet processing steps are varied using the methods 100, 120, and 140 of the invention for metal contact and wring formation such that contact resistance and wiring resistance during solar cell fabrication and the manufacturing cost thereof can be reduced. Fabrication of a silicon sheet and exemplary cross-sectional schematic views of the silicon sheet will be further described with respect to FIGS. 2A-2E, 3A-3F, and 4A-4B.

FIG. 2A-2E depict schematic views of a sheet 200 for forming metal contact on the surface thereof using method 100 of the invention in accordance with one or more embodiments of the invention. The sheet 200 may include various types of soalr cell p-n junctions therein and features, such as via and/or opening, on one or more surfaces of the substrate or sheet. In one embodiment, the sheet 200 of the invention may include vias formed for front side and/or back side contact and wiring before contact metallization. Optionally, vias on the surface of the sheet 200 are filled with metal materials using suitable film forming techniques; for example, vias and features on the surface of the sheet 200 can be filled by inkjet printing, among others. For solar cell fabrication, the front and/or the back surfaces of the sheet 200 may be textured to assist in light-trapping or light-confinement, and reduce reflection loss.

As shown in FIG. 2A, a thin film of an antireflective coating layer 202 and/or a passivation layer is deposited on the surface of the sheet 200. For example, the antireflective coating layer 202 can be, for example, a thin film of silicon nitride or silicon oxide material deposited inside a chemical vapor deposition chamber, such as a plasma enhanced chemical vapor deposition chamber, to a thickness between about 20 nm and 500 nm, such as a thickness of about 50 nm to about 250 nm, e.g., about 70 nm to about 200 nm. As an example, a silicon nitride layer can be deposited using a mixture of silicon-containing precursor and/or nitrogen-containing precursor, such as a mixture of silane gas, ammonium gas, hydrogen gas, and/or nitrogen gas, inside an parallel-plate radio-frequency (RF) plasma enhanced chemical vapor deposition (PECVD) system, available from AKT, a division of Applied Materials, Inc., Santa Clara, Calif., and good step coverage of the antireflective coating layer 202 can be obtained. Other suitable materials for the antireflective coating layer 202 include various dielectric materials, such as titanium oxide, amorphous carbon material, among others. Optionally, the surface of the antireflective coating layer 202 may be textured and additional layers of anti-reflection coating can be deposit for better index matching, such as a second front side dielectric antireflective coating layer.

In FIG. 2B, a pattern of a photoresist material 204 is formed on the surface of the antireflective coating layer 202 using suitable photoresist masks and photolithography patterning techniques. One example of forming a pattern of the photoresist material 204 is an ink jet printing technique. An optional dielectric layer or silicon oxide layer can be deposited prior to patterning the photoresist material 204 to be served as an etching mask.

In FIG. 2C, the photoresist material 204 is exposed to UV light or electron-beam before the antireflective coating layer 202 is etched as shown in FIG. 2D. For example, silicon nitride can be etched according to the pattern of the photoresist material using a wet etch chemistry of phosphoric acid at high temperatures, e.g., at around 175° C. Silicon oxide can be etched through the pattern of the photoresist material using a buffered oxide etch (BOE) solution containing hydrofluoric acid (HF). Other dry etch techniques, such as plasma etching, sputter etching, or reactive-ion etching, etc., can also be used. Next, the surface of the sheet 200 having a pattern of the photoresist material 204 is cleaned and/or dried,

As shown in FIG. 2E, a film stack containing a first metal material 206 and a second metal material 208 can be deposited on the surface of the sheet 200 to form into metal contact to the sheet 200. The first metal material 206 may be titanium, molybdenum, etc., deposited to a thickness of between about 20 nm and 50 nm, such as about 34 nm. The first metal material is used, after high temperature annealing, to form into a metal silicide material with the sheet 200 and thus reduce contact resistance of the devices fabricated on the sheet 200. The second metal material 208 may be copper, aluminum, silver, etc., to provide low resistivity for wiring formation and device fabrication on surface of the sheet 200 and also serve as a seed layer at a later fabrication step for forming metal lines, metal fingers, metal wirings of a semiconductor device. The second metal material can be deposited to a thickness of between about 50 nm and 250 nm, such as a thickness of about 170 nm. In FIG. 2E, the first metal material 206 and the second metal material 208 are also deposited on the surface of the photoresist material 204 and can be later removed after photoresist stripping.

In one embodiment, the first metal material 206 and the second metal material 208 are deposited using a physical vapor deposition process chamber of the invention available for various sheet sizes, such as those available from AKT, a division of Applied Materials, Inc., Santa Clara, Calif. However, it should be understood that the invention has utility in other system configurations, such as other physical vapor deposition systems, chemical vapor deposition systems, and any other film deposition systems.

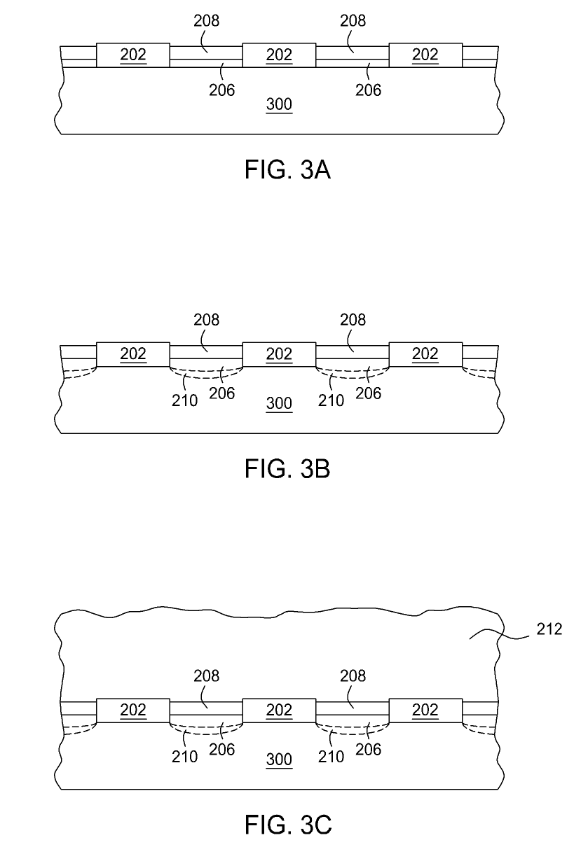

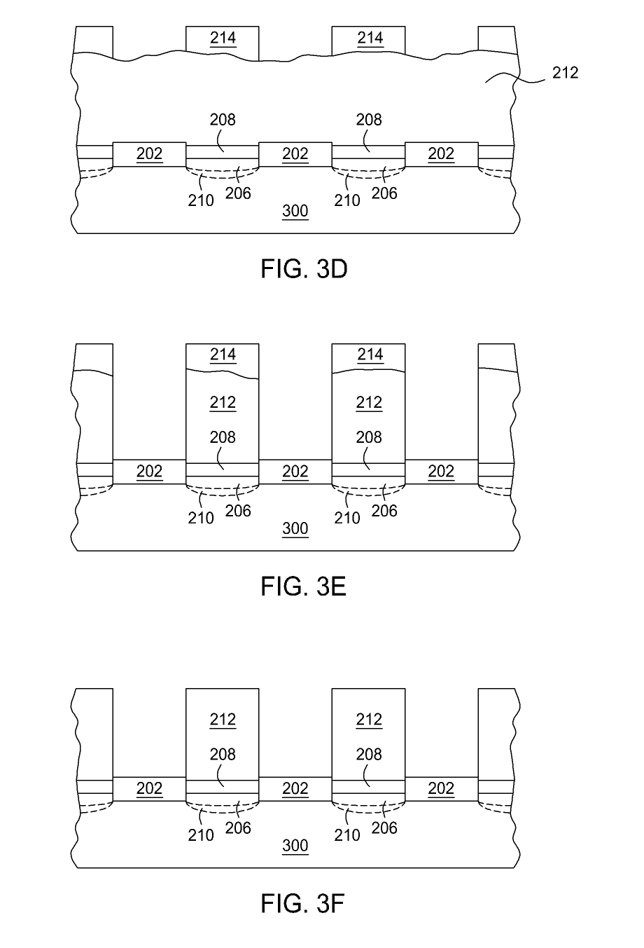

FIG. 3A-3F depict schematic views of a sheet 300 for forming metal contact and wiring on the surface thereof using method 120 of the invention in accordance with one or more embodiments of the invention. As shown in FIG. 3A, the silicon sheet 300 may include a pattern of the antireflective coating layer 202, the first metal material 206, and the second metal material 208 formed on the surface of a sheet, which may be the sheet 200, or any silicon sheets having various types of solar cell junctions or other p-n junctions thereon. The sheet 300 may need to be cleaned prior to further sheet processing to form into good contact with the junction thereon. For example, any photoresist material, impurities, or contaminants on the surface of the sheet 300 may need to be stripped off and cleaned using suitable solvents, water, or cleaning chemistries.

In FIG. 3A, a pattern of a film stack having the first metal material 206, and the second metal material 208 is formed on the surface of the sheet 300 for forming metal contacts between the boundary of the first metal material and the sheet 300 having p-n junctions thereon after annealing at high temperature, such as about 200° C. or higher.

In FIG. 3B, metal silicide materials 210, such as titanium silicide, molybdenum silicide, among others, are formed at the bottom of the film stack of the invention into good contact with the junctions of the sheet 300 after annealing and provide low contact resistance of the solar cell devices fabricated on the sheet 300.

In FIG. 3C, according to one or more aspects, a layer of a bulk metal material 212 is deposited over the surface of the sheet 300 using a physical vapor deposition technique, such as by sputtering a target containing the bulk metal material 212 inside a physical vapor deposition chamber of the invention. In one embodiment, the bulk metal material 212 is the same metal material as the second metal material 208, which may include copper, aluminum, silver, among others. In another embodiment, the thickness of the bulk metal material 212 for continued contact and wiring formation can be about 500 nm or larger, such as about 5,000 nm or larger, or between about 5,000 nm and 10,000 nm.

Further processing for forming features on the layer of the bulk metal material 212 may be needed. For example, as shown in FIG. 3D, a pattern of a photoresist material 214 in accordance with a predetermined wiring scheme may be formed on the surface of the sheet 300, such as by an inject printing technique or other suitable techniques. Other dielectric layers or silicon oxide layers can be deposited between the photoresist material 214 and the bulk metal material to be served as an etching mask. The photoresist material 214 formed into a wiring pattern is then cured and developed, such as by exposure to UV light, electron-beam, or other suitable photolithography techniques.

In FIG. 3E, the bulk metal material 212 is etched using suitable metal etching chemistries according to the pattern of the photoresist material 214 and, as shown in FIG. 3F, desired wiring pattern and features, such as contact lines or contact fingers, are formed on the surface of the sheet 300. The photoresist material 214 can be the same or different material as the photoresist material 204.

The surface of the sheet 300 may additionally need to be cleaned to remove surface impurities, etching residues, and/or contaminants. Optionally, the sheet 300 may need to be annealed. For example, when copper is deposited as the bulk metal material 212, annealing is required to form into a good conductor material and lower the overall resistance of the metal wiring.

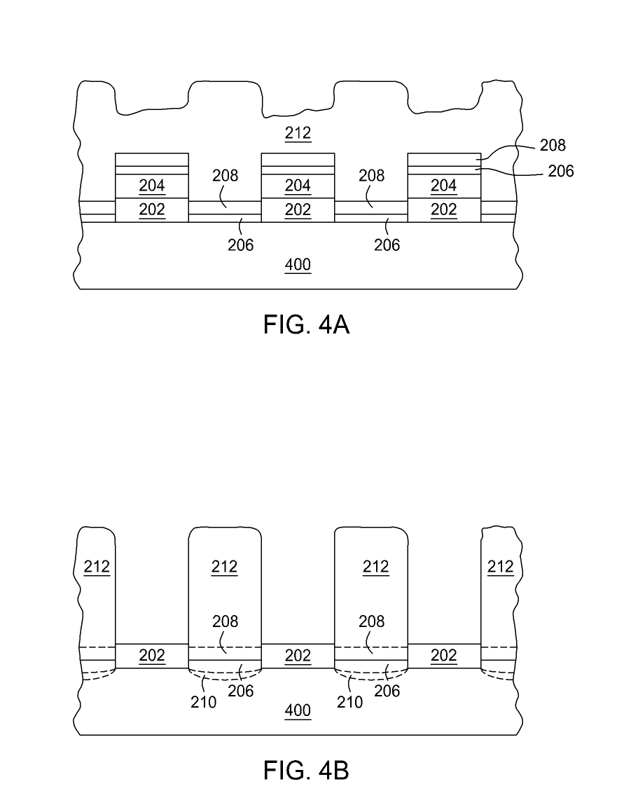

FIG. 4A-4B depict schematic views of a sheet 400 for forming metal contact and wiring on the surface thereof using method 140 of the invention in accordance with one or more embodiments of the invention. As shown in FIG. 4A, the surface of the sheet 400 may include a pattern of the antireflective coating layer 202, covered with a film stack containing the first metal material 206 and the second metal material 208. The sheet 400 may be the sheet 200 or any silicon sheets having various types of solar cell junctions or other p-n junctions thereon and other material layers for solar cell device fabrication. The sheet 400 may optionally be cleaned prior to further sheet processing.

According to one or more aspects of the invention, a metal material, such as the bulk metal material 212 is deposited on the surface of the sheet 400 using an electroplating sheet processing system. As shown in FIG. 4A, the sheet 400 may include a film stack containing the first metal material 206 and the second metal material 208 deposited thereon as a seed layer material for the bulk metal material 212 to continue the height of the metal contact and wiring formation. In another embodiment, the bulk metal material 212 is deposited using an electroless deposition system. Accordingly, the bulk metal material 212 may be the same metal material as the second metal material 208 and may include copper, aluminum, silver, among others, deposited to a thickness of about 100 nm or larger, such as about 1,000 nm or larger.

As shown in FIG. 4B, a pattern of the bulk metal material 212 is formed after stripping off the photoresist material 204 and desired contact lines, contact fingers, and/or wiring patterns are formed on the surface of the sheet 400. Additional annealing or surface cleaning steps may also be performed on the sheet 400. Alternatively, the phtoresist material 204 may be stripped off the surface of the sheet 400 before the bulk metal material 212 is electroplated or eletroless deposited onto the surface of the sheet.

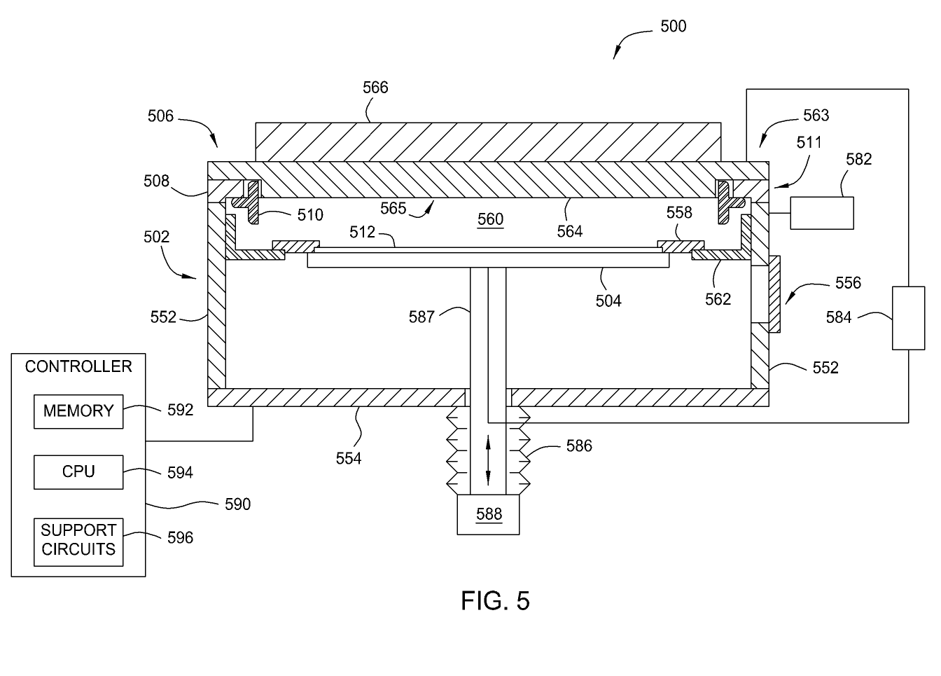

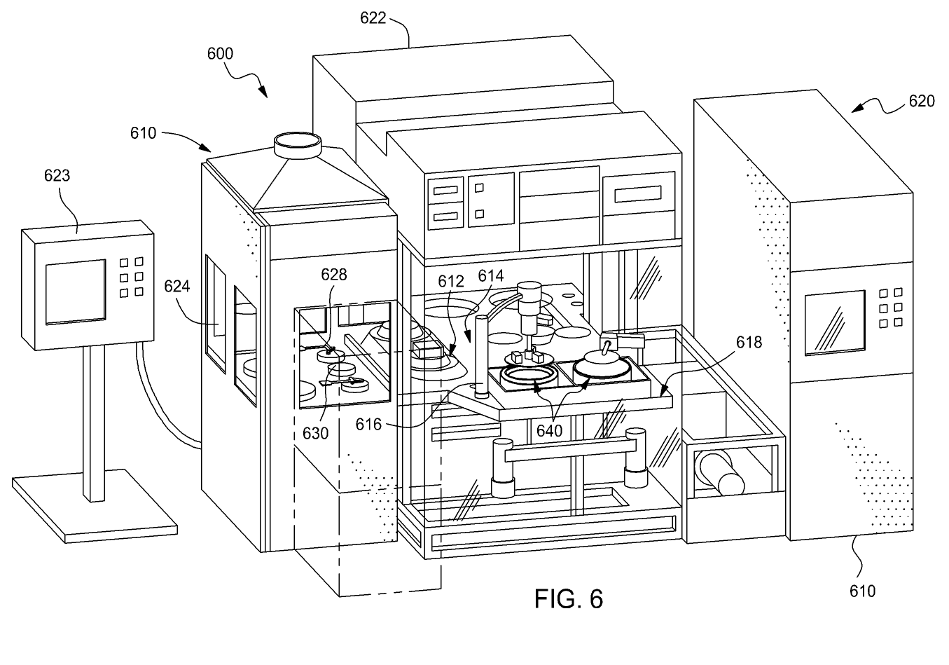

Suitable vacuum deposition chambers of the invention may include various physical vapor deposition chambers to deposit one or more metal materials for contact and wiring formation on a surface of a sheet. Alternatively, other film deposition systems, such as electroplating systems and electroless deposition systems are used to deposit the bulk metal material of the invention. In addition, annealing the sheet of the invention at high temperature, such as at a temperature of about 200° C. or higher, e.g., at about 1000° C., can be performed inside a furnace, such as those available from Tokyo Electronic Limited, or rapid thermal annealing chambers, such as those available from Applied Material Inc. The invention is illustratively described below in reference to a physical vapor deposition system in FIG. 5 and a electroplating system in FIG. 6, both available from Applied Materials, Inc., Santa Clara, Calif., for processing various types of sheets or substrates of the invention in various sheet sizes.

FIG. 5 is a schematic cross-sectional view of one embodiment of a physical vapor deposition process chamber 500, available from AKT, a division of Applied Materials, Inc., Santa Clara, Calif. A sheet processing system including one or more process chambers, one or more physical vapor deposition process chambers, sheet input/output chambers, a main transfer robot for transferring sheet among the sheet input/output chambers, and a mainframe controller for automatic sheet processing control can also be used for processing the sheet 200, 300, 400 in accordance with embodiments of the invention. The physical vapor deposition process chamber 500 includes a chamber body 502 and a lid assembly 506, defining a process volume 560. The chamber body 502 is typically fabricated from a unitary block of aluminum or welded stainless steel plates. The dimensions of the chamber body 502 and related components are not limited and generally are proportionally larger than the size and dimension of a sheet 512 to be processed in the physical vapor deposition process chamber 500.

The chamber body 502 generally includes sidewalls 552 and a bottom 554. The sidewalls 552 and/or bottom 554 generally include a plurality of apertures, such as an access port 556 and a pumping port (not shown). Other apertures, such as a shutter disk port (not shown) may also optionally be formed on the sidewalls 552 and/or bottom 554 of the chamber body 502. The access port 556 is sealable, such as by a slit valve or other mechanism, to provide entrance and egress of the sheet 512 (e.g., a solar cell sheet, a glass substrate, or a semiconductor wafer) into and out of the physical vapor deposition process chamber 500. The pumping port is coupled to a pumping system (also not shown) that evacuates and controls the pressure within the process volume 560.

The lid assembly 506 generally includes a target 564 and a ground shield assembly 511 coupled thereto. The target 564 provides a material source that can be deposited onto the surface of the sheet 512 during a PVD process. The target 564 or target plate may be fabricated of a material that will become the deposition species or it may contain a coating of the deposition species. To facilitate sputtering, a high voltage power supply, such as a power source 584 is connected to the target 564.

The target 564 generally includes a peripheral portion 563 and a central portion 565. The peripheral portion 563 is disposed over the sidewalls 552 of the chamber. The central portion 565 of the target 564 may protrude, or extend in a direction towards a sheet support 504. It is contemplated that other target configurations may be utilized as well. For example, the target 564 may comprise a backing plate having a central portion of a desired material bonded or attached thereto. The target material may also comprise adjacent tiles or segments of material that together form the target. Optionally, the lid assembly 506 may further comprise a magnetron assembly 566, which enhances consumption of the target material during processing.

During a sputtering process to deposit a material on the sheet 512, the target 564 and the sheet support 504 are biased relative each other by the power source 584. A process gas, such as inert gas and other gases, e.g., argon, and nitrogen, is supplied to the process volume 560 from a gas source 582 through one or more apertures (not shown), typically formed in the sidewalls 552 of the physical vapor deposition process chamber 500. The process gas is ignited into a plasma and ions within the plasma are accelerated toward the target 564 to cause target material being dislodged from the target 564 into particles. The dislodged material or particles are attracted towards the sheet 512 through the applied bias, depositing a film of material onto the sheet 512.

The ground shield assembly 511 includes a ground frame 508, a ground shield 510, or any chamber shield member, target shield member, dark space shield, dark space shield frame, etc. The ground shield 510 surrounds the central portion 565 of the target 564 to define a processing region within the process volume 560 and is coupled to the peripheral portion 563 of the target 564 by the ground frame 508. The ground frame 508 electrically insulates the ground shield 510 from the target 564 while providing a ground path to the chamber body 502 of the physical vapor deposition process chamber 500 (typically through the sidewalls 552). The ground shield 510 constrains the plasma within the region circumscribed by the ground shield 510 to ensure that target source material is only dislodged from the central portion 565 of the target 564. The ground shield 510 may also facilitate depositing the dislodged target source material mainly on the sheet 512. This maximizes the efficient use of the target material as well as protects other regions of the chamber body 502 from deposition or attack from the dislodged species or the from the plasma, thereby enhancing chamber longevity and reducing the downtime and cost required to clean or otherwise maintain the chamber. Another benefit derived from the use of the ground frame 508 surrounding the ground shield 510 is the reduction of particles that may become dislodged from the chamber body 502 (for example, due to flaking of deposited films or attack of the chamber body 502 from the plasma) and re-deposited upon the surface of the sheet 512, thereby improving product quality and yield.

Additional PVD chambers, targets, and magnetrons that may be adapted to benefit from the invention are described in co-pending U.S. patent application Ser. No. 10/863,152, filed on Jun. 7, 2004, titled “Two Dimensional Magnetron Scanning for Flat Panel Sputtering” by Tepman; Ser. No. 11/146,762, filed on Jun. 6, 2005, entitled “Multiple, Scanning Magnetrons” by Le et al.; Ser. No. 11/167,520, filed on Jun. 27, 2005, entitled “Method for Adjusting Electromagnetic Field across a Front Side of a Sputtering Target Disposed Inside a Chamber” by Le et al.; and (docket number: AMAT/10173) entitled “Evacuable Magnetron Chamber” by Inagawa et al., all of which are hereby incorporated by reference in their entireties.

The sheet support 504 is generally disposed on the bottom 554 of the chamber body 502 and supports the sheet 512 thereupon during sheet processing within the physical vapor deposition process chamber 500. The sheet support 504 may include a plate-like body for supporting the sheet 512 and any additional assembly for retaining and positioning the sheet 512, for example, an electrostatic chuck and other positioning means. The sheet support 504 may include one or more electrodes and/or heating elements imbedded within the plate-like body support. The temperature of the sheet 512 to be processed can thus be maintained to a desired temperature range.

A shaft 587 extends through the bottom 554 of the chamber body 502 and couples the sheet support 504 to a lift mechanism 588. The lift mechanism 588 is configured to move the sheet support 504 between a lower position and an upper position. The sheet support 504 is depicted in an intermediate position in FIG. 5. A bellows 586 is typically disposed between the sheet support 504 and the chamber bottom 554 and provides a flexible seal therebetween, thereby maintaining vacuum integrity of the process volume 560.

Optionally, a shadow frame 558 and a chamber shield 562 may be disposed within the chamber body 502. The shadow frame 558 is generally configured to confine deposition to a portion of the sheet 512 exposed through the center of the shadow frame 558. When the sheet support 504 is moved to the upper position for processing, an outer edge of the sheet 512 disposed on the sheet support 504 engages the shadow frame 558 and lifts the shadow frame 558 from the chamber shield 562. When the sheet support 504 is moved into the lower position for loading and unloading the sheet 512 from the sheet support 504, the sheet support 504 is positioned below the chamber shield 562 and the access port 556. The sheet 512 may then be removed from or placed into the physical vapor deposition process chamber 500 through the access port 556 on the sidewalls 552 while cleaning the shadow frame 558 and the chamber shield 562. Lift pins (not shown) are selectively moved through the sheet support 504 to space the sheet 512 away from the sheet support 504 to facilitate the placement or removal of the sheet 512 by a transfer robot 430 or a transfer mechanism disposed exterior to the physical vapor deposition process chamber 500, such as a single arm robot or dual arm robot. The shadow frame 558 can be formed of one piece or it can be two or more work-piece fragments bonded together in order to surround the peripheral portion of the sheet 512.

PVD chambers that may be adapted to benefit from the invention are described in co-pending U.S. patent application Ser. No. 11/131,009 (docket number: AMAT/9566) filed on May 16, 2005, titled “Ground Shield for a PVD chamber” by Golubovsky; (docket number: AMAT/10230), titled “Substrate Movement and Process Chamber Scheduling” by White et al.; and Ser. No. 11/167,377 (docket number: AMAT/10172) filed on Jun. 27, 2005, titled “Process Kit Design to Reduce Particle Generation” by Le et al., all of which are hereby incorporated by reference in their entireties.

As shown in FIG. 5, a controller 590 is included to interface with and control various components of the physical vapor deposition process chamber 500. The controller 590 typically includes a central processing unit (CPU) 594, support circuits 596 and a memory 592. The CPU 594 may be one of any form of computer processor that can be used in an industrial setting for controlling various chambers, apparatuses, and chamber peripherals. The memory 592, any software, or any computer-readable medium coupled to the CPU 594 may be one or more readily available memory devices, such as random access memory (RAM), read only memory (ROM), hard disk, CD, floppy disk, or any other form of digital storage, for local or remote for memory storage. The support circuits 596 are coupled to the CPU 594 for supporting the CPU 594 in a conventional manner. These circuits include cache, power supplies, clock circuits, input/output circuitry, subsystems, and the like.

FIG. 6 depicts one example of an electrochemical plating system that may be used herein, such as an Electra integrated Electro-Chemical Plating (iECP) System or a Slim Cell plating system, available from Applied Materials, Inc., of Santa Clara, Calif. In addition, any system enabling electrochemical processing using the methods or techniques described herein may also be used.

An electroplating system platform 600 generally includes a loading station 610, a spin-rinse-dry (SRD) station 612, a mainframe 614, and an electrolyte replenishing system 620. Additionally, the electroplating system platform 600 may be enclosed in a clean environment using panels, such as plexiglass panels.

The mainframe 614 generally includes a mainframe transfer station 616 and a plurality of processing stations 618. Each processing station 618 includes one or more processing cells 640. An electrolyte replenishing system 620 is positioned adjacent the electroplating system platform 600 and connected to the processing cells 640 individually to circulate electrolyte used for the electroplating process. The electroplating system platform 600 also includes a control system 622, typically a programmable microprocessor. The control system 222 also provides electrical power to the components of the system and includes a control panel 623 that allows an operator to monitor and operate the electroplating system platform 600.

The loading station 610 typically includes one or more sheet cassette receiving areas 624, one or more loading station transfer robots 628 and at least one sheet orientor 630. The number of sheet cassette receiving areas, loading station transfer robots 628, and sheet orientor 630 included in the loading station 610 can be configured according to the desired throughput of the system. A sheet cassette containing a plurality of sheets is loaded onto the sheet cassette receiving area 624 to introduce sheets into the electroplating system platform 600.

The loading station transfer robot 628 transfers sheets between the sheet cassette and the sheet orientor 630. The sheet orientor 630 positions each sheet in a desired orientation to ensure that each sheet is properly processed. The loading station transfer robot 628 also transfers sheets between the loading station 610 and the SRD station 612.

Although the invention has been described in accordance with certain embodiments and examples, the invention is not meant to be limited thereto. The PVD process and electroplating process described herein can be carried out using other PVD chambers or plating systems, adjusting various processing parameters, pressure, and temperature so as to obtain high quality films at practical deposition rates. It is understood that embodiments of the invention include scaling up or scaling down any of the process parameter/variables as described herein according to sheet sizes, chamber conditions, etc., among others.

While the foregoing is directed to embodiments of the present invention, other and further embodiments of the invention may be devised without departing from the basic scope thereof, and the scope thereof is determined by the claims that follow.

1. A method for forming metal contact and wiring on a sheet, comprising:
depositing an antireflective coating layer on the surface of the sheet;
forming a pattern of a photoresist material for contact metallization on the surface of the sheet;
curing the photoresist material;
etching the antireflective coating layer through the pattern of the photoresist material;
cleaning the surface of the sheet;
depositing a film stack having the first metal material and a second metal material over the surface of the sheet inside a physical vapor deposition chamber;
stripping the photoresist material off the surface of the sheet;
annealing the sheet for forming good contact between the film stack and the sheet; and
depositing a bulk metal material over the surface of the sheet.

2. The method of claim 1, wherein the antireflective coating layer comprises silicon nitride formed inside a chamber selected from the group consisting of a plasma enhanced chemical vapor deposition chamber (PECVD) and a physical vapor deposition chamber (PVD).

3. The method of claim 1, wherein the pattern of the photoresist material is formed by inkjet printing.

4. The method of claim 1, wherein the first metal material comprises a material selected from the group consisting of nickel, titanium, molybdenum, their alloys, and combinations thereof.

5. The method of claim 1, wherein the second metal material comprises a material selected from the group consisting of copper, silver, aluminum, their alloys, and combinations thereof.

6. The method of claim 1, wherein the bulk metal material is deposited over the surface of the sheet inside a process chamber selected from the group consisting of a physical vapor deposition chamber, an electroplating cell, an electroless deposition chamber.

7. The method of claim 1, wherein stripping the photoresist material is performed before the bulk metal material is deposited over the surface of the sheet.

8. The method of claim 1, wherein stripping the photoresist material is performed after the bulk metal material is deposited over the surface of the sheet.

9. The method of claim 1, wherein annealing is performed inside a chamber selected from the group consisting of an annealing furnace and a rapid thermal processing chamber.

10. The method of claim 1, further comprising depositing a passivation layer over the surface of the sheet.

11. The method of claim 1, further comprising forming features before the antireflective coating layer is deposited over the surface of the sheet.

12. The method of claim 11, further comprising filling features with metal materials.

13. The method of claim 1, further comprising forming a pattern of a second photoresist material after depositing the bulk metal material on the surface of the sheet.

14. The method of claim 1, wherein the first metal material is deposited to a thickness of between about 40 nm and about 80 nm.

15. The method of claim 1, wherein the first metal material is deposited to a thickness of between about 50 nm and about 300 nm.

16. The method of claim 1, wherein the first metal material is deposited to a thickness of about 500 nm or larger.

17. A method for forming metal contact and wiring on a sheet, comprising:
depositing an antireflective coating layer on the surface of the sheet;
forming a pattern of a photoresist material for contact metallization on the surface of the sheet;
curing the photoresist material;
etching the antireflective coating layer through the pattern of the photoresist material;
cleaning the surface of the sheet;
depositing a film stack having the first metal material and a second metal material over the surface of the sheet inside a physical vapor deposition chamber;
depositing a bulk metal material over the surface of the sheet inside an electroplating system.

18. The method of claim 17, further comprising stripping the photoresist material off the surface of the sheet after the bulk metal material is deposited.

19. The method of claim 17, further comprising stripping the photoresist material off the surface of the sheet before the bulk metal material is deposited.

20. The method of claim 17, further comprising annealing the sheet for forming good contact between the film stack and the sheet.

21. The method of claim 17, further comprising forming a pattern of a second photoresist material.

22. The method of claim 21, further comprising etching the bulk metal material.

23. A method for forming metal contact and wiring on a sheet, comprising:
depositing an antireflective coating layer on the surface of the sheet;
forming a pattern of a photoresist material for contact metallization on the surface of the sheet;
curing the photoresist material;
etching the antireflective coating layer through the pattern of the photoresist material;
cleaning the surface of the sheet;
depositing a film stack having the first metal material and a second metal material over the surface of the sheet inside a physical vapor deposition chamber;
stripping the photoresist material off the surface of the sheet;
annealing the sheet for forming good contact between the film stack and the sheet; and
depositing a bulk metal material over the surface of the sheet inside an electroless deposition system.

24. The method of claim 23, further comprising stripping the photoresist material off the surface of the sheet.
